(19) United States
(12) Patent Application Publication
(10) Pub. No.: US 2003/0068832 A1
(43) Pub. Date: Apr. 10, 2003

(54) Submicron closed-form josephson junctions

(76) Inventors: Yuri Koval, Erlangen (DE); Alexey V. Ustinov, Effeltrich (DE); Jeremy P. Hilton, Vancouver (CA)

Correspondence Address: Pennie & Edmonds, LLP, 3300 Hillview Avenue, Palo Alto, CA, 94304, US

(21) Appl. No.: 10/233,211

(22) Filed: Aug. 28, 2002

Related U.S. Application Data
(60) Provisional application No. 60/315,969, filed on Aug. 29, 2001.

(51) Int. Cl. H01L 21/00

(52) U.S. Cl. 438/2

(57) ABSTRACT

A method for fabricating a closed-form Josephson junction includes etching the inner shape of the closed-form junction on the chip, depositing a negative photoresist material over the etched chip, and flood exposing the backside of the chip with ultraviolet radiation. The photoresist is developed and then baked onto the chip. The baked photoresist serves as a mask for subsequent etching of the exterior of the closed-form Josephson junction. A shaped Josephson junction is fabricated with junction widths between about 0.1 μm and about 1 μm and an inner diameter ranging between about 1 μm and about 1000 μm.

### CROSS REFERENCE TO RELATED APPLICATIONS

This application claims priority from U.S. Provisional Patent Application No. 60/315,969, “Fabrication Method For A Submicron Shaped Josephson Junction,” filed on Aug. 29, 2001. U.S. Provisional Patent Application No. 60/315,969 is incorporated herein in its entirety by this reference.

### FIELD OF THE INVENTION

This invention relates to solid state superconducting structures as well as the fabrication of solid state superconducting structures.

### BACKGROUND

Referring to FIG. 9, a closed-form long Josephson junction 900 includes two superconducting materials 904, also referred to as electrodes 904-1 and 904-2, separated by insulating material 906. Superconducting material 904 can be a conventional superconductor, such as niobium (Nb) or aluminum (Al). The insulating material can be aluminum oxide (Al₂O₃). The shape of the interface between electrodes 904-1 and 904-2 has closed-form geometry. The characteristics of the junction are defined in part by the shape of this closed-form geometry. Typically, the shape of the closed-form geometry is annular as illustrated in FIG. 9. In such instances, the junction is described as a ring-shaped tunnel junction between two electrodes.

A unique property of annular long Josephson junctions, such as junction 900 (FIG. 9), results from the quantization of magnetic flux in the superconducting ring. In other words, closed-form superconducting systems, such as superconducting ring 900, trap magnetic flux in a quantized manner. This effect, also referred to as perfect diamagnetism, occurs because magnetic fields are excluded from thick samples of superconducting material. In one example of flux quantization, Meissner and Ochsenfeld demonstrated that the magnetic flux trapped in a, a closed-form, simply connected, superconducting structure with an aperture, is quantized in multiples of h/2e. The value h/2e is known in the art as the flux quantum or fluxon and is often denoted with the symbol Φ₀. The symbol h is Plank's constant, and e is elementary charge. A fluxon has a value of 2.07×10⁻¹⁵ Weber. See M. Tinkham, 1995, Introduction to Superconductivity, 2nd ed., McGraw-Hill, especially pages 2-22, which is herein incorporated by reference in its entirety. Quantization of magnetic flux is a unique feature of superconductivity that can occur in structures more general than closed-form long Josephson junction 900.

Annular junction 900 is a topologically closed-form superconducting system. Therefore the net number of initially trapped fluxons is conserved. New fluxons can be created within junction 900 only in the form of fluxon-antifluxon pairs. See, e.g., Davidson et al., 1985, Phys. Rev. Lett. 55, 2059, which is hereby incorporated by reference. Fluxon motion in annular junctions 900 occurs under periodic boundary conditions and without any reflections from boundaries. This avoids many mathematical and physical complications that occur for fluxon motion in other junction shapes. One source of the interest in investigating annular junctions derives from fundamental aspects of the Berry phase effect that arises in annular junctions. See, e.g, Gaitan, 2001, Phys. Rev. B 63, 104511-1; and Plerou and Gaitan, 2001, Phys. Rev. B 63, 104512-1, which are hereby incorporated by reference in their entirety. Interest also arises from the phenomenon of Cherenkov radiation by solitons on long annular junctions. See, e.g., Goldobin et al., 1998, Phys. Rev. B 57, 130; and Wallraff et al., 2000, Phys. Rev. Lett. 84, 151, which are hereby incorporated by reference in their entirety. Cheronkov radiation exists if a particle moves with a velocity equal to the phase velocity of the emitted waves. Fluxons trapped in long Josephson junctions have also been proposed as on-chip clocks by Zhang and Gupta, 1999, Supercond. Sci. Technol. 12, 769; as well as Gupta and Zhang, 2000, Appl. Phys. Lett. 76, 3819, which are hereby incorporated by reference in their entirety.

Annular junctions with uniform submicron widths and symmetric shapes are particularly useful in applications such as quantum computing. Referring to FIG. 9, a junction has a submicron width when dimension d is less than one micron. One advantage of the present invention is that junctions that have a uniform dimension d can be fabricated even when d is less than 1 micron. In one embodiment of the present invention, d is uniform when it does not deviate by more than five percent from a minimum or maximum d throughout the junction. In another embodiment, d is uniform when it does not deviate by more than 0.05 microns from a minimum or maximum throughout the junction. The fabrication of junctions 900 with submicron widths and symmetric shapes remains a challenge. Wallraff et al. describe the fabrication of an annular junction with a sub-micron width. See Wallraff et al., 2000, J. Low Temp. Phys. 118, 543, which is hereby incorporated by reference. However, the techniques taught by Wallraff have limited reproducibility and are further limited to a narrow range of junction diameters and terminal widths.

In general, known fabrication methods require precise alignment of several layers to properly form the junction. This alignment is done manually for every junction on the chip. This alignment must be exact, without allowance for deviations due to material defects or shifts and distortions in the alignment. A misalignment of even 0.1 μm for a junction with a 1 μm width (e.g., d in FIG. 8) has a significant adverse effect on the electrical performance of the junction as well as the potential profile of the junction. Current fabrication methods cannot achieve the necessary uniformity in the geometrical characteristics of junctions 900 that have a width d of less than 1 μm. As a result, current fabrication methods cannot achieve satisfactory uniformity in the electrical properties of junctions 900. Furthermore, known fabrication methods for junctions 900 are not reproducible. Accordingly, more reproducible fabrication methods for submicron closed-form Josephson junctions are needed in the art.

### SUMMARY OF THE INVENTION

In accordance with the present invention, methods for fabricating a uniform shaped Josephson junction are presented. In one embodiment in accordance with the present invention, a commercially available trilayer chip is the starting point for the reproducible fabrication of uniform submicron closed-form Josephson junctions. The trilayer chip includes an upper electrode layer, an insulator layer and a lower electrode layer. In the method, the inner shape of the closed-form junction is etched into the chip. This etching process removes the upper electrode layer, the insulator layer and the lower electrode layer, exposing a portion of the substrate that has the form of the closed-form junction. Then, a negative photoresist material is deposited over the chip. The negative photoresist material coats covers the chip, including the etched away area of the chip. The negative photoresist material in then exposed using backside illumination through the chip using a wavelength of light that can penetrate the substrate but not the upper and lower electrode material. In this way, only those regions of the photoresist that lie in the etched portions of the substrate are exposed to the irradiation. Therefore, in subsequent photoresist development, only the photoresist in the vicinity of the etched region remains. Further processing steps are then performed in order to insulate the junction, add junction terminals, and connect an upper electrode to the junction terminal. The disclosed fabrication method is used to improve the reproducibility and accuracy of junction insulation, terminal formation as well as electrode attachment.

In some embodiments, the trilayer chip includes an upper superconducting layer, an insulating layer, and a lower superconducting layer on a substrate. The substrate is transparent to radiation used to expose photoresist materials. In one embodiment of the present invention, the substrate is transparent to ultraviolet radiation. In one embodiment, the substrate is sapphire that is transparent to ultraviolet radiation. The superconducting layers consist of any superconducting material. Examples of superconducting material include, but are not limited to Nb and Al. The insulating layer is any insulator known in the art. A representative insulator is aluminum oxide (Al₂O₃). The superconducting trilayer structures used in the present invention are fabricated by known methods.

Some embodiments of the present invention produce closed-form Josephson junctions having a maximum inner width d (FIG. 8) that is in the range of about 0.1 μm to about 1 μm. Some embodiments of the present invention produce closed-form Josephson junctions having a maximum outer width w (FIG. 9) that is in the range of about 1 μm to about 1000 μm.

Some embodiments of the present invention take advantage of patterned structures on the chip to mask exposure of photoresist material during photolithography. In other words, the junction structure itself forms the mask for the photoresist. This effectively results in self-alignment of the mask, thereby reducing the number of steps required to make the closed-form Josephson junction. Furthermore, a novel baking procedure is used to precisely control the width d (FIGS. 8 and 9) of the junction.

These and other embodiments of the present invention are further discussed below in conjunction with the following figures.

### BRIEF DESCRIPTION OF THE FIGURES

FIGS. 1A and 1B illustrate a cross-sectional view of an etched tri-layer chip.

FIG. 2 illustrates a cross-sectional view of the photoresist that remains on an etched tri-layer chip after backside exposure and development in accordance with one embodiment of the present invention.

FIG. 3 illustrates a cross-sectional view of photoresist on an etched tri-layer chip after baking in accordance with one embodiment of the invention.

FIG. 4 illustrates a cross-sectional view of an etched tri-layer chip in which remaining photoresist serves as a mask for etching the chip, in accordance with one embodiment of the invention.

FIG. 5A illustrates a cross-sectional view of a sample after formation of the terminal to the lower superconducting electrode using etching and subsequent removal of photoresist, in accordance with one embodiment of the invention.

FIG. 5B illustrates a plan view of an embodiment of the invention prior to the formation of an upper electrode, in accordance with one embodiment of the present invention.

FIG. 6 illustrates a cross-sectional view of an embodiment of a junction with insulated sides, in accordance with one embodiment of the invention.

FIG. 7 illustrates a cross-sectional view of an embodiment of the invention with isolated junction terminals.

FIG. 8 illustrates a cross-sectional view of the junction with a connection to the top superconducting electrode.

FIG. 9 illustrates a closed-form Josephson junction in accordance with the prior art.

FIGS. 10A and 10B illustrate a heart shaped closed-form Josephson in accordance with the prior art.

Like reference numerals refer to the corresponding parts throughout the several views of the drawings.

### DETAILED DESCRIPTION OF THE INVENTION

### Closed-form Josephson Junctions

Recently, closed-form Josephson junctions have been proposed for the creation, storage and manipulation of quantum bits (“qubits”) in the form of fluxons. See, e.g., U.S. patent application Ser. No. 09/637,514 to Ustinov, herein incorporated by reference in its entirety. As long as the Josephson junction adopts a closed form, it is possible to trap an elementary quantum of magnetic flux (fluxon) in the junction. See, e.g., Ustinov, 1998, Physica D 123, 315, which is hereby incorporated by reference. Noncircular closed-form Josephson junctions trap fluxons in a discrete manner in the same manner as annular Josephson junctions. A fluxon trapped in closed-form Josephson junction (e.g., junction 900) can be manipulated by applying magnetic fields perpendicular or parallel to the plane of the junction. For example, when a magnetic field is applied parallel to the plane of a closed-form Josephson junction, a pinning potential will fix a trapped fluxon at a specific point in the junction. Alternatively, a bias current passing between the electrodes of the closed-form junction creates a pinning potential in the junction that can be used to manipulate the location of the fluxon within the closed-form junction.

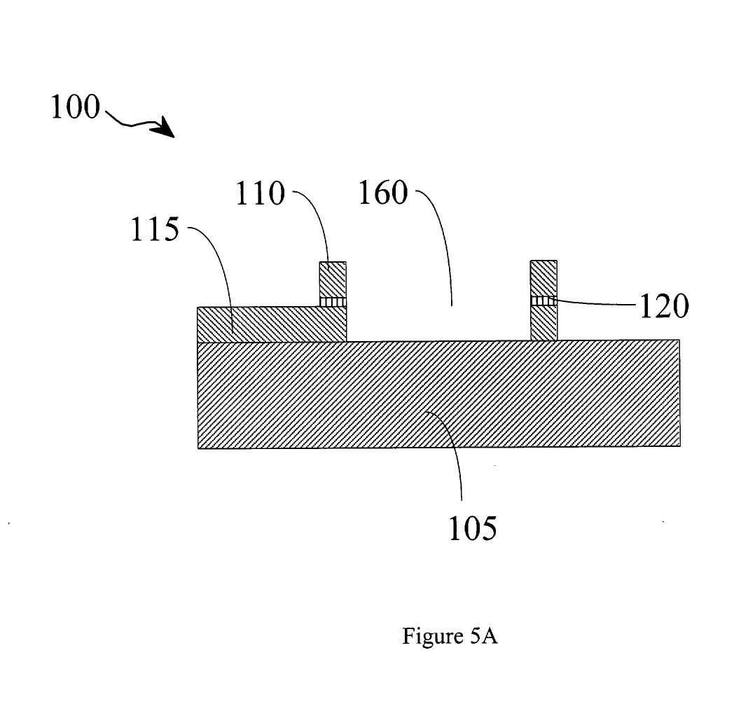

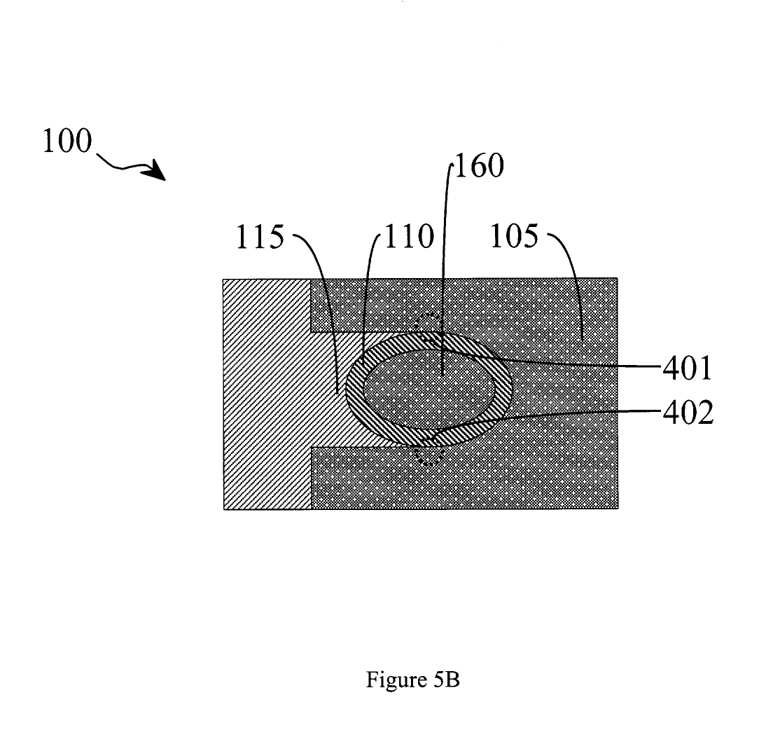

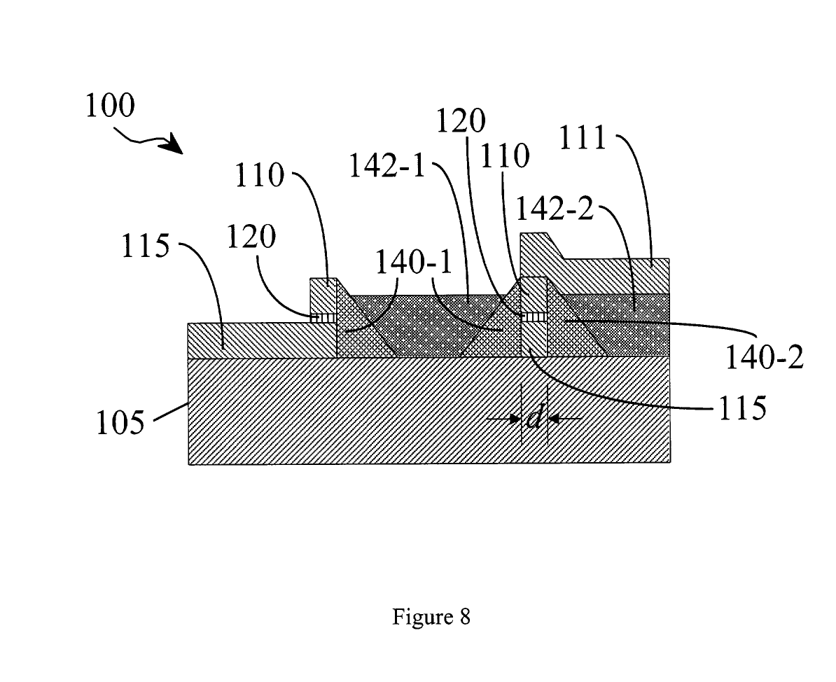

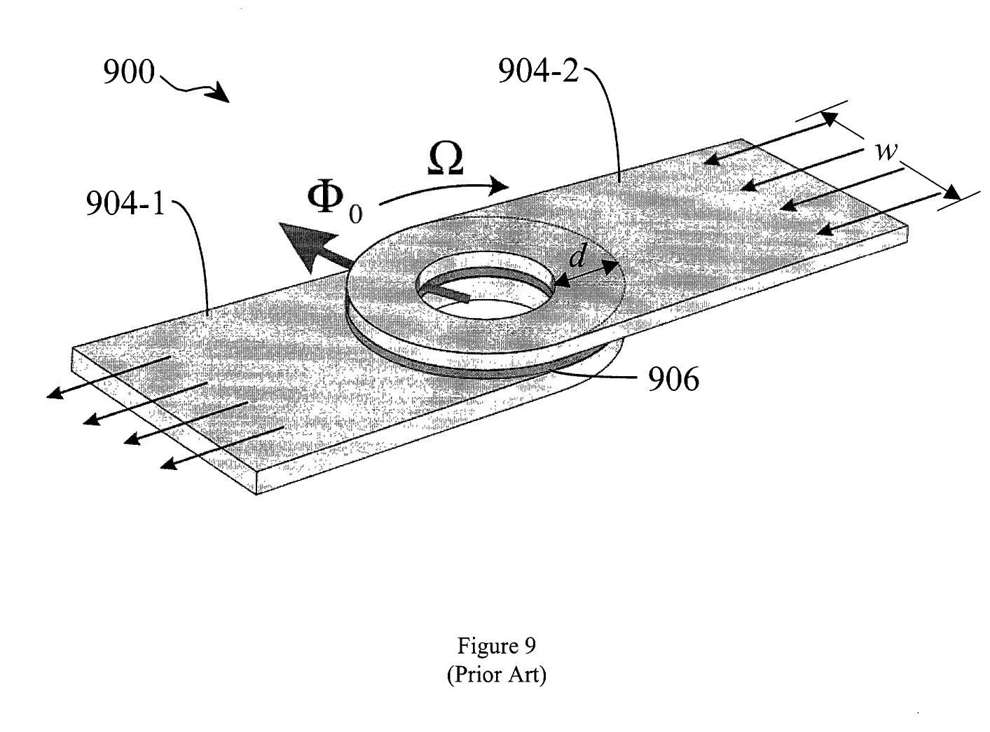

In closed-form Josephson junctions, a fluxon has a potential energy at each position in the junction that is significantly determined by the width and shape of the Josephson junction at that position. For example, a Josephson junction with a perfectly uniform width d (FIGS. 8 and 9) and circular shape in the absence of external biasing, such as a bias current or external magnetic fields, has a uniform potential at all positions in the junction. As such, there is no single stable point for the fluxon. If however, some part of the junction has a greater width than other parts of the junction, or has a non-constant surrounding stripline, or any other type of defect, the potential at that point will dip. The stripline is the area of the closed-form Josephson junctions that is patterned on the substrate. It corresponds to the patterned region of superconducting material covered by the insulating material that comprises the Josephson junction (e.g., insulating layer 120 of FIG. 5A). This localized dip in the fluxon potential energy is referred to as a pinning center. See, e.g., Franz et. al., 2001, J. Appl. Phys. 89, 471, which is hereby incorporated by reference in its entirety.

### The Use of Closed-form Josephson Junctions in Quantum Computing

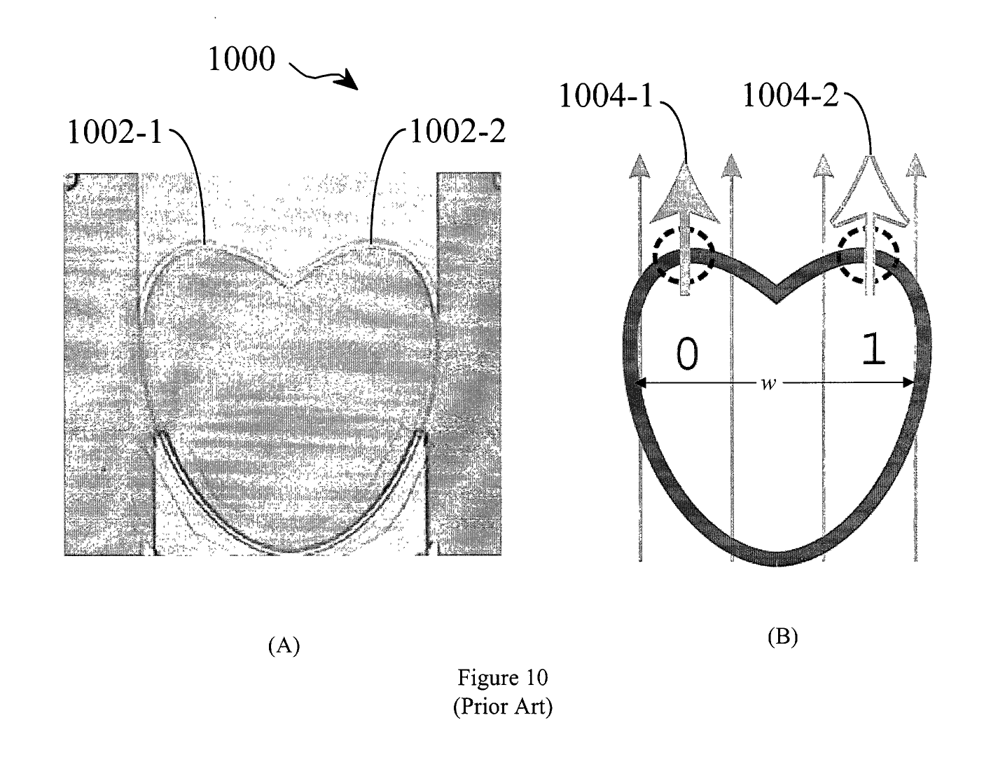

Pinning centers in closed-form Josephson junctions can be used for application in quantum computing. If a closed-form Josephson junction has a heart shape (e.g., junction 1000, FIG. 10A), in which two symmetric lobes 1002 (FIG. 10A) are formed in the junction, then two pinning centers 1004 (FIG. 10B) can be created. If the shape is symmetric and uniform then, given a symmetric bias with a magnetic field or bias current, the pinning potential at each of the lobes is equal 1002, and the pinning centers 1004 become doubly degenerate, the potential energy function for the junction forms a double well. The double well in the potential energy diagram that describes the closed-form Josephson junction can be used in a form of quantum computing. In this form of quantum computing the junction (e.g., junction 1000, FIG. 10A) is a qubit and the pinning locations (e.g. pins 1004, FIG. 10B) form the basis states of the qubit.

Quantum computing is accomplished using the effects of physical systems that exhibit quantum mechanical behavior, such as qubits. A qubit is a physical system that is restricted to two or more quantum states. The quantum states may be used to store information. A qubit is a quantum bit, the counterpart in quantum computing to the binary digit or bit of classical computing. Just as a bit is the basic unit of information in a classical computer, a qubit is the basic unit of information in a quantum computer. A qubit is conventionally a system having two quantum states. The quantum state of the qubit can be in a superposition of the two quantum states. The two states, or in fact two or more states, can be degenerate. States are degenerate when they have the same energy. The two degenerate states are also referred to as basis states. The two degenerate or basis states are often denoted |0 [symbol] and |1 [symbol] . See, for example, Tinkam, Introduction to Superconductivity, Robert E. Krieger Publishing Company, Inc., 1980; Nielsen & Chuang, Quantum Computation and Quantum Information, Cambridge University Press, 2000; and Braunstein and Lo eds., Scalable Quantum Computers, Wiley-VCH, New York, 2001, which are hereby incorporated by reference in their entirety.

A qubit can be in any superposition of two degenerate (basis) states, making it fundamentally different from a bit in an ordinary digital computer. A superposition of states arises in an n-state system (e.g., a qubit) when there is a non-zero probability that the system occupies more than one of the basis states at a given time. If certain conditions are satisfied, N qubits can define an initial state that is a combination of 2^{N} classical states. This initial state undergoes an evolution, governed by the interactions that the qubits have among themselves and with external influences, providing quantum mechanical operations that have no analogy with classical computing. The evolution of the states of N qubits defines a calculation or, in effect, 2^{N} simultaneous classical calculations. Reading out the states of the qubits after evolution completely determines the results of the calculations.

For a quantum computer to be of practical value, the number of qubits in the computer must be at least 10⁴. See Mooij et al., Science 285, p. 1036 (1999), which is hereby incorporated by reference in its entirety. Qubits have been implemented in cavity quantum dynamic systems, ion traps, and nuclear spins of large numbers of identical molecules. However, such systems are not particularly well suited for the realization of the desired high number of interacting qubits needed in a quantum computer.

### Fabrication of Closed-form Josephson Junctions

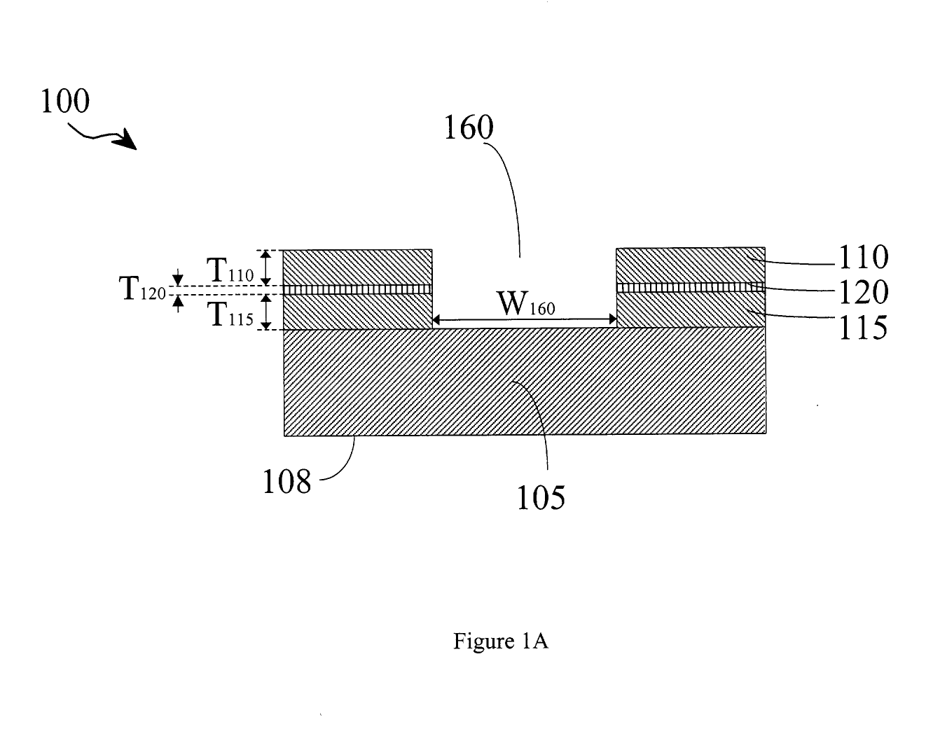

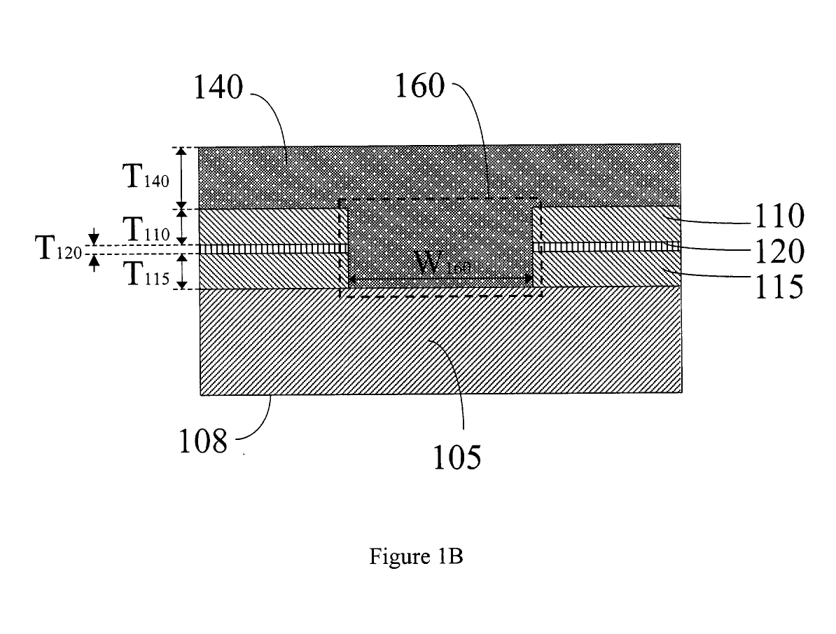

The present invention addresses the need for fabricating suitable closed-form Josephson junctions. FIG. 1A shows a cross-section of a trilayer chip 100 that is used to make a closed-form Josephson junctions in accordance with some methods of the present invention. Methods for fabricating trilayer chips 100 that include a substrate 105, a first superconducting layer 115, an insulating layer 120, and a second superconducting layer 110 are known. Superconducting foundries, such as Hypres, Inc. (Elmsford, N.Y.), for example, manufacture and sell such chips with conventional superconducting materials. Superconducting layer 115 has a thickness T₁₁₅, insulating layer 120 has a thickness T₁₂₀, and superconducting layer 110 has a thickness T₁₁₀. In some embodiments T₁₁₅ and T₁₁₀ are about 100 nm to about 300 nm. In some embodiments T₁₂₀ is about 1 nm to about 20 nm.

Trilayer chip 100 is etched in a first step in the fabrication process in order to form etched region 160 (FIG. 1A). Then, photoresist layer 140, having a minimum thickness T₁₄₀ is deposited onto chip 100 (FIG. 1B). In some embodiments the photoresist used to make photoresist layer 140 is an organic negative photoresist. In some embodiments T₁₄₀ is about 0.2 μm to about 1 μm. In some embodiments, substrate 105 is transparent to the radiation utilized to expose photoresist layer 140. In some embodiments, substrate 105 is sapphire. Sapphire has advantageously low absorption levels in high frequency applications. Consequently, sapphire is transparent to ultraviolet radiation. Superconducting layer 115 is any conventional superconducting material including, but not limited to, Nb, Al and Pb. In some embodiments, the thickness of superconducting layer 115 is about 50 nm to about 500 nm. In some embodiments, the thickness of superconducting layer 115 is about 100 nm to about 500 nm. In some embodiments, insulating layer 120 is made of aluminum-aluminum oxide (Al—AlOₓ). In some embodiments, insulating layer 120 has a thickness of about 0.5 nm to about 40 nm. In some embodiments, insulating layer 120 has a thickness of about 1 nm to about 20 nm. In some embodiments, superconducting layer 110 is formed of the same material as superconducting layer 115. In some embodiments, superconducting layer 110 is formed of a different material than superconducting layer 115. In some embodiments, superconducting layer 110 has a thickness of about 5 nm to about 500 nm. In some embodiments, superconducting layer 110 has a thickness of about 10 nm to about 300 nm.

Etched region 160 (FIG. 1A) has the inner shape of the desired closed-form Josephson junction. The desired closed-form shape is any closed form, including, but not limited to, oval shaped (as illustrated), circular shaped (not illustrated) and heart-shaped (FIG. 10). In FIG. 1A, region 160 shows where layers 110, 120, and 115 have been etched to form the closed-form Josephson junction. The contours of region 160, when photoresist 140 layer has been removed, are illustrated in FIG. 5B (FIG. 5B, 160). FIG. 5B shows a top plan view of the closed-form Josephson junction. As illustrated in FIG. 5B, a circular shape 160 of a specific radius has been etched into layers 110, 120, and 115. In some embodiments, a plurality of closed-form Josephson junctions are fabricated on the same substrate 105 by etching a plurality of regions 160 into trilayer chip 100.

Etched region 160 can have any closed form shape. For example, in some applications, it is useful to create a junction having a heart shape. A heart shaped Josephson junction is illustrated in FIG. 10. In FIG. 10, heart shaped junction 1000 (FIG. 10) results in two pinning centers 1002. A fluxon can be trapped and manipulated between centers 1002. The width of etched region 160 (w, FIG. 10B) varies between about 1 micron and about 1000 microns, in accordance with some embodiments of the invention. Region 160 can be etched into chip 100 using any etching technique known in the art, including, but not limited to, ion beam etching, reactive ion etching, electron cyclotron resonance plasma etching. See, e.g., Lichtenberger et al, 1991, IEEE Trans. Magn. 27, 3168; Aoyagi et al., 1997, IEEE Transactions on Applied Superconductivity 7, 2644, and Van Zant, Microchip Fabrication, Fourth Edition, 2000, McGraw-Hill, New York, each of which is herein incorporated by reference in their entirety.

In some embodiments, negative photoresist layer 140 is deposited over layer 110 after region 160 has been etched into chip 100. Those portions of the negative photoresist that are not irradiated will dissolve during a subsequent development procedure. Those portions of the negative photoresist that are irradiated will not dissolve during a subsequent development procedure. In one example, a first region of negative photoresist is covered or masked while a second region of the negative photoresist remains unmasked. The entire sample is then irradiated. After irradiation, the mask is removed and chip 100 is put through a development solution. In the development solution, the masked (unexposed) first region dissolves while the unmasked (exposed) second region remains. The mask is used to pattern the sample with the required structures. Thus, the mask must be properly aligned so that the pattern can be accurately formed. Photoresist layer 140 may comprise any negative photoresist. In some embodiments, photoresist layer 140 has a resolution of about 1 micron or better. Deposition of resist layer 140 is accomplished by any process known in the art, including, but not limited to, spin coating and pulverization. See Van Zant, Microchip Fabrication, Fourth Edition, 2000, McGraw-Hill, New York, which is hereby incorporated by reference in its entirety.

In some embodiments the thickness of resist layer 140 (FIG. 1, T₁₄₀) is about 0.2 μm to about 1 μm. Information on resist thickness versus deposition parameters for individual resist materials is available, for example, from resist suppliers. One useful photoresist material is cross-linked polymethylmethacrylate (PMMA). Many other photoresist materials are available and all such materials are within the scope of the present invention. Positive electron resist PMMA can be turned negative by exposing the PMMA to a high electron exposure dose. See, e.g., Koval et al., 1999, IEEE T. Appl. Supercon. 9, 3957, which is hereby incorporated by reference in its entirety.

FIG. 1B illustrates a cross-sectional view of an etched region of chip 100 and an overlying photoresist layer 140. In some embodiments, substrate material 105 is any substrate that is transparent to, for example, ultraviolet radiation. In some embodiments, substrate 105 is sapphire. Layers 115 and 110 are superconducting materials such as Nb. Layers 115 and 110 each have thickness of about 100 nm to about 300 nm. Layer 120 is any insulating material. A representative insulating material used to make layer 120 is Al—AlOₓ. In some embodiments of the present invention, layer 120 has a thickness T₁₂₀ of about 1 nm to about 20 nm. In some embodiments of the present invention, layer 120 has a thickness of about 0.5 nm to about 40 nm. Etched region 160 has a maximum width W₁₆₀ that is application dependent.

The closed-form created by etched region 160 (FIG. 1) is any closed geometry. The only limitations on the shape of the closed form of region 160 are manufacturing limitations. Currently, these manufacturing limitations require that the maximum inner width W₁₆₀ is within the range of about one micron to about 1000 microns. However, larger ranges are contemplated by the present invention as manufacturing limitations change. In some embodiments of the present invention, photoresist layer 140 has a thickness T₁₄₀ (FIG. 1A) of about 0.2 μm to about 2 μm. The thickness of photoresist layer 140 plays a role in determining the width d (FIGS. 8 and 9) of the junction terminals.

When a photomask is used to pattern resist layers, there is typically a gap between the resist layer and the photomask. Unfortunately, the size of this gap often varies across the desired junction. A variable gap between a resist and a photomask causes uneven diffraction and interference near the edge of the photomask. This leads to imperfections in the desired junction, especially when the diameter of the junction is less than a micron.

The present invention provides an alternative to using a conventional mask in order to pattern photoresist 160. Rather than carefully aligning a mask over region 140 that matches the contours of region 160 as done in conventional techniques, the present invention uses layers 110, 115, and 120 in etched chip 100 as a mask to a backside illumination source. In such embodiments, substrate 105 is substantially transparent to the radiation source while layers 115, 120, and 110 (FIG. 11B) block the illumination source. Alternatively, at least one of layers 115, 120, and 110 blocks this illumination source. An advantage of using layers 115, 120 and 110 as a mask for exposure of photoresist 140 is that there is no gap between resist layer 140 and a photomask. This removes the possibility for imperfections in the desired junction due to a variable gap between a photomask and the photoresist. Thus, the only region of photresist layer that is exposed to the backside illumination source is region 160 (FIG. 11B). Region 160 is the only region of layer 140 that becomes cross-linked and therefore will not dissolve away in a subsequent development step.

In some embodiments, backside ultraviolet radiation is used to expose photoresist layer 140. The use of light exposure in photolithography is known. See, for example, Voschenkov et al., 1980, Electron. Lett. 17, 61; and Yoshikawa et al., 1981, Jpn. J. Appl. Phys. 20, 181, which are hereby incorporated by reference in their entirety. In some embodiments, chip 100 is flood irradiated in order to expose photoresist layer 140. The flood radiation is homogenous across the entire back surface 108 of chip 100 (e.g., the surface opposite layer 115). When chip 100 is irradiated from the backside, layers 115, 120, and 110 act together as a mask. The use of layers 115, 120, and 110 as a mask for photo-exposure serves as a mechanism for self-alignment of the mask that advantageously removes the need for further steps associated with aligning a mask to the junction.

In the present invention, any system of photoresist and radiation source that will effectively expose (e.g., crosslink) the photoresist can be used. The only requirement is that the substrate is sufficiently transparent to the radiation source so that the photoresist can be exposed. The use of ultraviolet radiation and a sapphire substrate has been disclosed. However, other radiation sources and substrates that are transparent to the radiation source can be used, provided that such radiation sources effectively expose (e.g., crosslink) the photoresist.

After the sample has been exposed to radiation, it is developed by rinsing the sample in a developer (e.g., a chemical solution). The developer removes the photoresist material. When a negative photoresist is used, the regions that are unexposed to radiation are removed by the developer, while the exposed regions are not removed by the developer. Rinsing of the exposed sample in a developer is a standard photolithographic step. The composition of developers depends upon the composition of the photoresist material used to make layer 140 (FIG. 1). Photoresist material, and the developers for such materials, are commercially available. The exposure dose used to develop layer 140 and the development time (e.g., the amount of time photoresist layer 140 is exposed to a developer) vary depending on the type of photoresist used.

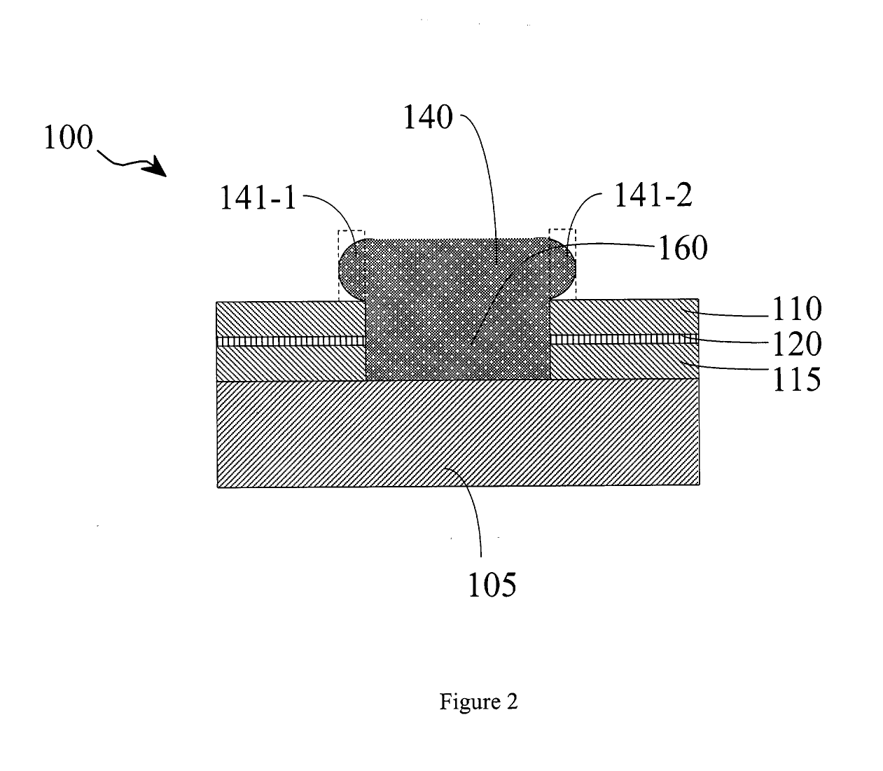

FIG. 2 shows chip 100 after removal of unexposed photoresist. As illustrated, overhangs 141-1 and 141-2 remain after the unexposed photoresist is removed. Resist thickness affects the profile of overhangs 141-1 and 141-2. Overhangs 141-1 and 141-2 can be used to adjust the width of the closed-form Josephson junction. The width of overhangs 141 can be varied using deposition, exposure, and development parameters. For example, the thickness of photoresist 140 can be increased in order to increase the width of overhangs 141. An increase in the width of overhangs 141 will increase the total width d (FIGS. 8 and 9) of the Josephson junction. Therefore, deposition, exposure, and development parameters can be used to vary the total width of the junction.

In some embodiments of the present invention, chip 100 is baked after it has been developed. In one embodiment, this baking comprises heating the sample in order to cause photoresist layer 140, which is typically a glass, to flow with a high viscosity. When it flows, overhangs, 141-1 and 141-2 (FIG. 2) relax back onto the top surface of layer 110. The longer the sample is baked, the further photoresist 140 will flow. More extensive photoresist flow yields a greater junction width. Junction width, therefore, is a function of the photoresist thickness and the profile of the photoresist before heating. The heating temperature used to bake chip 100 depends on the resist material used. An upper bound to the heating temperature is dictated by the tolerance of resist material to heating. For example, the upper temperature for AlOₓ, which can be a constituent of insulating layer 120, is about 160° C. In some embodiments, chip 100 is baked in an oven or on a hotplate. In some embodiments of the present invention, the baking temperature during at least a portion of the baking is between about 120° C. and about 160° C.

In some embodiments of the present invention, photoresist has a thickness of about 200 nm to about 2000 nm. In some embodiments, overhangs 141-1 and 141-2 are uniform over the entirety of the closed-form geometry of etched region 160. In such embodiments, the flow of the photoresist is also uniform and therefore matches the closed-form geometry of the structure.

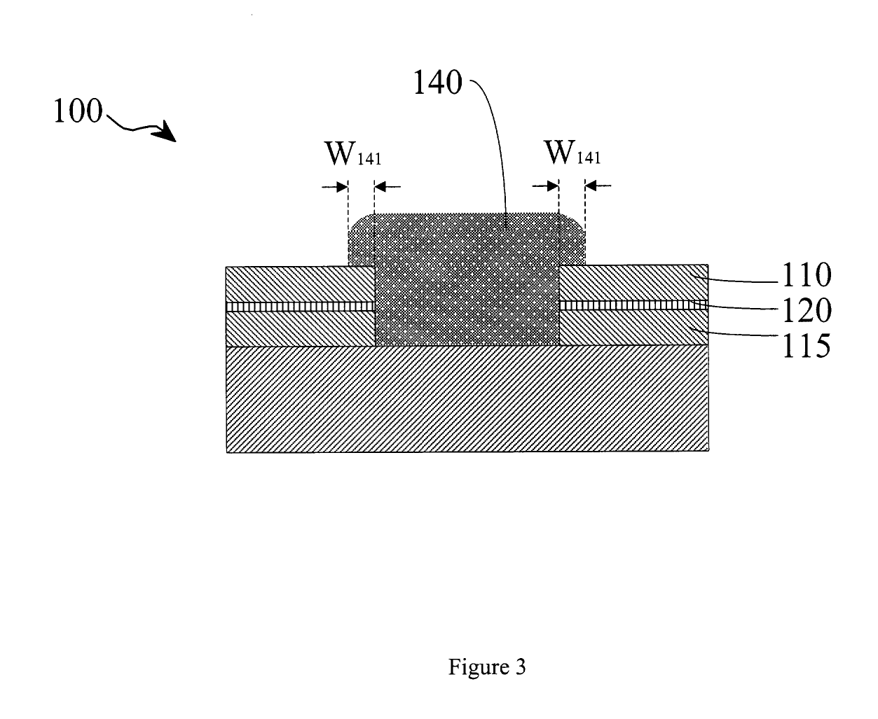

FIG. 3 illustrates a cross section of chip 100 after baking. Overhangs 141-1 and 141-2 of photoresist layer 140 have relaxed onto the top surface of layer 110 in a controlled manner. In some embodiments, width W₁₄₁ is uniform around the entire closed-form geometry. In such embodiments, overlaps 141-1 and 141-2, then, define the shape of the junction area.

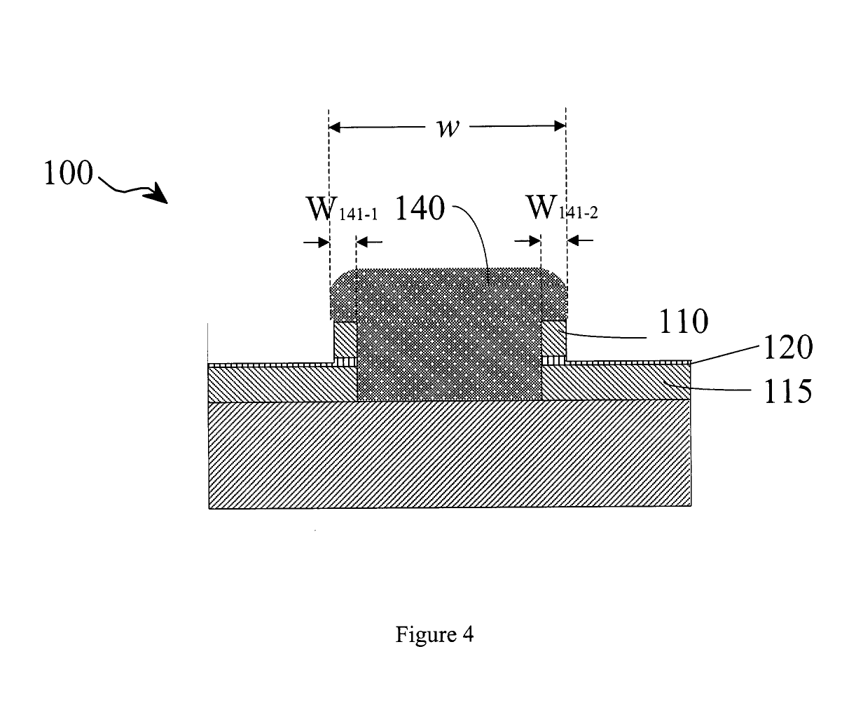

FIG. 4 shows chip 100 after etching using photoresist 140 with overhangs 141-1 and 141-2 as a mask. The removal of upper superconducting layer 110 by etching, using the remaining photoresist as a mask (including overhangs 141), defines the exterior of the closed-form Josephson junction. Etching, in accordance with this aspect of the invention, includes any form of dry etching that provides anisotropic etching of superconducting layer 110, has good selectivity of etching of layer 110 as opposed to photoresist 140, and allows for the use of insulating layer 120 as a stop layer. In some embodiments, layers 110 and 115 are formed of different superconducting materials so that layer 115 can function as a stop layer for this etching process. In some embodiments of the invention, layers 110 and 115 are both made of Nb. In some embodiments of the invention, reactive ion etching or electron cyclotron resonance plasma etching is used to etch layer 110.

The maximum outer junction terminal width w (FIG. 4) is determined by the width of overhangs 141 (FIG. 4, W₁₄₁₋₁ and W₁₄₁₋₂). Further control of junction terminal outer width is realized by the duration of the etching process. For example, junction terminal outer width w (FIG. 4) is decreased by under-etching the sample. Embodiments of the present invention can make use of a variety of methods to control the junction outer terminal width w and to alter the width of the overhangs, W₁₄₁₋₁ and W₁₄₁₋₂. In some embodiments of the invention, widths W₁₄₁₋₁ and W₁₄₁₋₂ depend on the intensity of exposure of the resist, how the resist is processed, and the duration of baking. A wide variety of shapes of overhangs are therefore possible. Factors that affect the width of overhangs 141 are known in the art. Therefore, they can be altered to suit design choices. The removal of the overhangs is dependent on earlier design choices. In some embodiments, removal of the overhangs is performed by known etching protocols. Variation of methods, to account for different overhang widths and profiles, is possible.

Lower superconducting layer 115 serves as one of the two electrodes that are connected to the closed-form Josephson junction. Accordingly, in some embodiments of the present invention, portions of superconductor layer 115 are removed in order to provide space for the addition of the upper electrode. FIG. 5A illustrates a side cross-sectional view of a sample after partial removal of layer 115. FIG. 5B illustrates a top plan view of a sample after partial removal of layer 115. Known bulk etching and/or lithographic steps are used to remove select regions of layer 115 in order to produce the structure illustrated in FIGS. 5A and 5B.

In the embodiment illustrated in FIG. 5B, the closed-form Josephson junction has an elliptical shape. In some embodiments, photoresist is used to facilitate selective removal of layer 115. For example, the remaining portions of layer 115 may need to be patterned to reduce stray capacitance between layer 115 and another component. In such embodiments, a mask is deposited for protection of the junction during etching (not shown in FIG. 5B). With proper masking in place, techniques similar to the methods described above are used to remove layer 115 from select regions. Preparation of the mask may include the backside exposure, development, and baking described above. Once the mask has been prepared as such, an additional mask can be added using, for example, a lithographic method that allows precision alignment of points 401 and 402 (FIG. 5B). Alignment with respect to points 401 and 402 can be easier than alignment to the entire perimeter. In some embodiments, etching of the remaining insulating layer 120 is performed by Argon etching. In some embodiments, layer 115 is then etched by reactive ion etching or electron cyclotron resonance plasma etching.

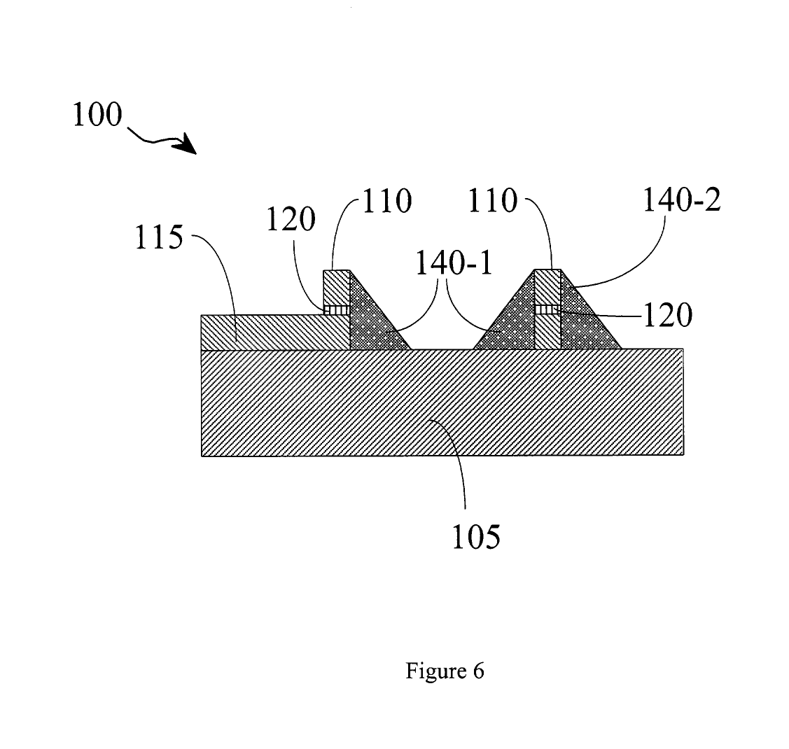

In some embodiments, the junction sides are insulated before region 110 is connected to the top superconducting electrode. Methods for insulating closed-form Josephson junctions are known. One method for insulating the junction border uses resist crosslinking by electron beam exposure. See, e.g., Koval et al., 1999, IEEE T. Appl. Supercon. 9, 3957. FIG. 6 illustrates a cross-sectional view of a sample with junction borders insulated by a resist that was formed using a resist crosslinking method. Resist materials 140-1 and 140-2 insulate the border of the junction and provide a base for deposition of an electrode for the upper layer of the trilayer structure. In some embodiments, the junction borders are insulated with the same negative photoresist used in previous stages of the inventive method. In some embodiments of the present invention, the insulating material is cross-linked PMMA.

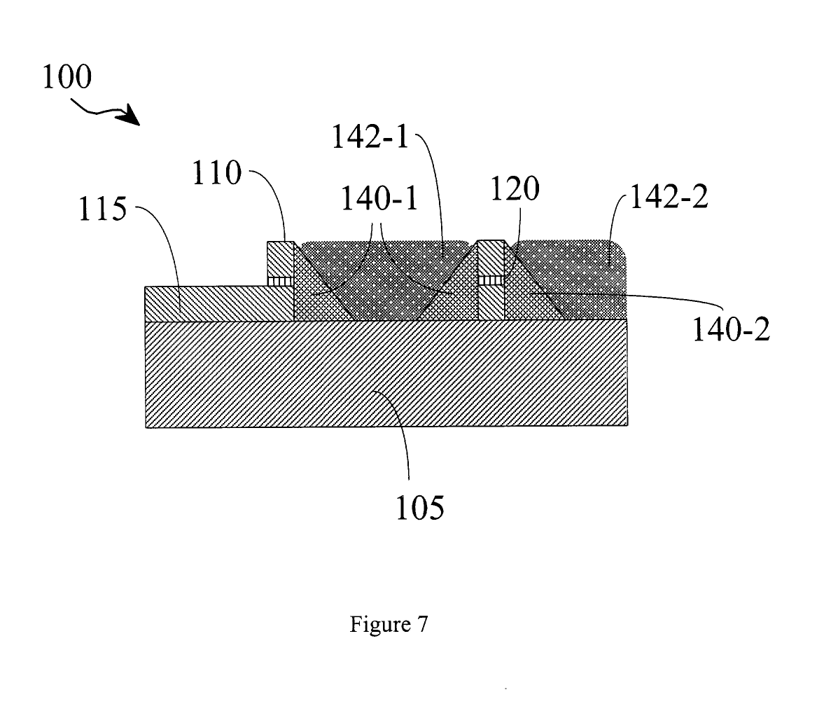

Another stage of fabrication includes the addition of the upper superconducting electrode. The upper superconducting electrode provides an interface with the junction to facilitate the application of bias current and measurements. In some embodiments of the invention, methods similar to those described in detail above are used to insulate the junction terminals and further provide a good connection between the junction terminals and the electrode to be attached. A method for preparing the junction terminals for insulation includes depositing a layer of negative photoresist over the entire sample, backside exposure of the sample with ultraviolet flood radiation, and subsequent development of the sample to remove unexposed regions of mask. The exposure and development times are application dependent. Over-exposure of the photoresist causes complete insulation of the junction terminals, thus preventing attachment of any electrode to layer 110. Under-exposure of the photoresist leaves the junction improperly insulated. In some embodiments of the invention, the resulting insulator adjoins the junction terminal sides, leaving no overhang on top layer 110, and having rounded corners on the top. FIG. 7 illustrates a cross-sectional view of an embodiment of the invention in which a negative photoresist material has been deposited, backside exposed with ultraviolet flood radiation, and developed to facilitate connection of an electrode to the junction terminal layer 110. The result of this process is the formation of resist 142-1 and 142-2.

In one embodiment of the inventive method, a layer (e.g., about 100 to about 500 nm) of photoresist is deposited on the structure illustrated in FIG. 6. The sample is then backside exposed with ultraviolet flood radiation that is not absorbed by substrate 105 but is absorbed by layer 115. The photoresist is then developed. Next, electron beam exposure is used to fix (e.g., crosslink) the resist near the borders of the junction. In one specific example, image reversal resist AZ5214E of about 0.5 μm thickness is deposited and exposed to a dose of about 1 milliCouries per square centimeter (mC/cm²) of electrons with energy about 20 keV. The remaining resist that was not cross-linked is removed in a chemical solution over a duration that is application dependent. For example, for the AZ5214E resist, non-cross-linked portions can be removed by acetone in about five minutes. In another embodiment of the invention, the non-cross-linked portions of the resist are left on the sample. In some embodiments, regions of resist material are stabilized with methods other than electron beam exposure, e.g., x-ray irradiation with appropriate conditions.

FIG. 7 illustrates a cross-sectional view of a sample in which insulating resists 142-1 and 142-2 are negative photoresist. Regions 142-1 and 142-2 may be formed using the following steps. First, a photoresist layer (not shown) is added to the top of structure 100. Then, the photoresist layer is backside illuminated with ultraviolet radiation using layers 110, 115, and 120 as a mask. That is, because illumination cannot penetrate layers 110, 115, and 120, only those regions of the photoresist that are in contact with substrate 105 are actually exposed to the backside illumination. Therefore, after development of the photoresist layer, only those regions that are in contact with substrate 105 will remain. As illustrated in FIG. 7, the remaining areas of the resist are 142-1 and 142-2.

After formation of crosslinked resist 142-1 and 142-2, an upper terminal (electrode) is formed. In typical embodiments, the upper terminal is formed using the same material used to make layer 110. FIG. 8 illustrates a cross-sectional view of an embodiment of the invention that includes an upper terminal 111 (electrode). Upper terminal 111 is connected to layer 110. In some embodiments of the present invention, electrode 111 is connected to a portion of layer 110 by the deposition, lithographic, and/or etching techniques described above. Some embodiments of the present invention connect electrode 111 to layer 110 using electron beam lithography, deposition, and lift-off. Thus, as seen in FIG. 8, the completed structure has an upper electrode 111, a closed-form Josephson junction formed by layers 110, 120, and 115. Furthermore, layer 115, extending to the left in FIG. 8, serves as the lower electrode. Various parts in FIG. 8 correspond to the closed-form Josephson junction shown in FIG. 9. Upper electrode 111 (FIG. 8) corresponds to part 904-2 (FIG. 9). Insulating layer 120 (FIG. 8) corresponds to insulating layer 906 (FIG. 9). Lower layer 115 (FIG. 8) corresponds to layer 904-1. While various parts in FIG. 8 correspond to the various parts in the prior art structure illustrated in FIG. 9, it will be appreciated that there are a number of novel distinctions between the structure disclosed in FIG. 8 and prior art structures such as FIG. 9. In particular, using the methods of the present invention, the structures illustrated in FIG. 8 have a precise closed-form geometry that has a maximum width d (FIGS. 8 and 9) that is typically less than one micron. Fabrication of a Josephson junction with precise closed-form geometry is accomplished, in part, by using the superconducting and insulating layers as a mask for a photoresist layer.

All references cited herein are incorporated by reference in their entirety and for all purposes to the same extent as if each individual publication or patent or patent application is specifically and individually indicated to be incorporated by reference in its entirety for all purposes. While closed-form Josephson junctions have been described in this application, it will be appreciated that the methods of the present invention can be used to manufacture Josephson junctions that do not have a closed form. Although the invention has been described with reference to particular embodiments, the description is only examples of the invention's applications and should not be taken as limiting. Various adaptations and combinations of features of the embodiments disclosed are within the scope of the invention as defined by the following claims.

We claim:

1. A method of fabricating a closed-form Josephson junction comprising:
forming an interior of a closed-form shape in a trilayer chip, wherein said trilayer chip comprises a substrate, a first superconducting layer, an insulating layer, and a second superconducting layer;
depositing a negative photoresist on said trilayer chip;
exposing the backside of said trilayer chip with an illumination source;
removing a region of said negative photoresist that has not been exposed to said illumination source; and
etching the chip to form an exterior of said closed-form Josephson junction.

2. The method of claim 1, wherein said substrate is transparent to said illumination source and wherein at least one of said first superconducting layer, said insulating layer, and said second insulating layer block said illumination source.

3. The method of claim 2, wherein said illumination source is ultra-violet (UV) radiation.

4. The method of claim 1, wherein said substrate is sapphire.

5. The method of claim 1, wherein said first superconducting layer comprises niobium (Nb), aluminum (Al), or lead (Pb).

6. The method of claim 1, wherein said second superconducting layer comprises niobium (Nb), aluminum (Al), or lead (Pb).

7. The method of claim 1, wherein said first superconducting layer and said second superconducting layer are made of different superconducting materials.

8. The method of claim 1, wherein a thickness of the first superconducting layer and a thickness of said second superconducting layer is about 100 nm to about 300 nm.

9. The method of claim 1, wherein said insulating layer comprises aluminum-aluminum oxide (Al—AlO_{X}).

10. The method of claim 1, wherein a thickness of said insulating layer is about 1 nm to about 20 nm.

11. The method of claim 1, the method further comprising:
baking said negative photoresist after said exposing; and
removing said exposed negative photoresist.

12. The method of claim 11, wherein the temperature of during at least a portion of said baking is about 120° C. and about 160° C.

13. The method of claim 1, wherein said forming comprises ion beam etching, reactive ion etching, or electron cyclotron resonance plasma etching.

14. The method of claim 1, wherein said negative photoresist is an organic negative photoresist.

15. The method of claim 1, wherein a thickness of said negative photoresist is between about 0.2 μm and 2 μm.

16. The method of claim 1, wherein said negative photoresist comprises cross-linked polymethylmethacrylate (PMMA) that is made by exposing PMMA to an electron exposure dose.

17. The method of claim 1, wherein an average exterior width of said closed-form Josephson junction is greater than about 1 μm and less than about 1000 μm.

18. The method of claim 1, wherein said exposing comprises flood radiation, wherein the backside of said trilayer chip is uniformly exposed with said illumination source.

19. The method of claim 1, wherein said removing comprises developing said chip in a chemical solution.

20. The method of claim 1, wherein said etching comprises etching a region of said first superconducting layer.

21. The method of claim 1, wherein said etching comprises ion beam etching, reactive ion etching, or electron cyclotron resonance plasma etching.

22. The method of claim 1, wherein said etching includes etching said insulating layer.

23. The method of claim 22, wherein said etching includes argon (Ar) sputtering.

24. The method of claim 1, the method further comprising attaching an electrode to said second superconducting layer.

25. A method for insulating a closed-form Josephson junction, the method comprising:
depositing a layer of negative photoresist on a chip, wherein said chip includes said closed-form Josephson junction;
backside irradiating said chip; and
developing said chip to remove unexposed regions of said negative photoresist.

26. The method of claim 25, wherein said backside irradiating comprised ultraviolet flood radiation that is directed at the substrate side of said chip.

27. A method for attaching an electrode to a closed-form Josephson junction, the method comprising:
depositing a photoresist mask on a chip, wherein said chip includes at least one insulated closed-form Josephson junction;
irradiating said photoresist mask with an illumination source;
developing said chip;
fixing said photoresist mask; and
depositing a superconducting material on said chip, thereby attaching said top electrode to said closed-form Josephson junction.

28. The method of claim 27, wherein a thickness of said photoresist mask is between about 100 nm and about 500 nm.

29. The method of claim 27, wherein said irradiating comprises ultraviolet flood radiation directed at a substrate side of said chip.

30. The method of claim 27, wherein said fixing comprises electron beam exposure of said chip that forms a region of cross-linked photoresist.

31. The method of claim 30, the method further comprising developing said chip to remove a region of said photoresist that is not cross-linked.

32. The method of claim 27, wherein said exposing comprises x-ray irradiation to form a region of cross-linked photoresist.

33. The method of claim 27, wherein said photoresist mask comprises polymethylmethacrylate.

34. The method of claim 27, wherein said photoresist mask includes AZ5214E.

35. The method of claim 27, wherein said photoresist mask is exposed to a dose of about 1 milliCouries per square centimeter (mC/cm²) with electrons having energy of about 20 kilo-electron Volts (keV).

36. A supercomputing structure comprising a closed-form Josephson junction, wherein said closed-form junction is manufactured by:
forming a closed-form shape in a trilayer chip, wherein said trilayer chip comprises a substrate, a first superconducting layer, an insulating layer, and a second superconducting layer;
depositing a negative photoresist on said trilayer chip;
exposing the backside of said trilayer chip with an illumination source;
removing a region of said negative photoresist that has not been exposed to said illumination source; and
etching the chip to form said closed-form Josephson junction.

37. The supercomputing structure wherein said closed-form junction is heart shaped.
